(19) United States
(12) Patent Application Publication
(10) Pub. No.: US 2006/0109148 A1
(43) Pub. Date: May 25, 2006

(54) Binary image-processing device and method using symbol dictionary rearrangement

(75) Inventor: Jong-hyon Yi, Yongin-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/263,018

(22) Filed: Nov. 1, 2005

(30) Foreign Application Priority Data
Nov. 22, 2004 (KR) 2004-95859

(51) Int. Cl. H03M 7/00

(52) U.S. Cl. 341/50

(57) ABSTRACT

Disclosed is binary image-processing device and method using symbol dictionary rearrangement. The binary image-processing device comprises a symbol-extracting unit for extracting symbols from an inputted binary image; a symbol-matching unit for matching a extracted symbol with a previously registered symbol and building a symbol dictionary; and a symbol dictionary rearrangement unit for re-arranging the symbol dictionary. The present invention re-arranges symbols extracted from binary images, thereby bringing an advantage of eliminating the conventional inefficiency caused by registering the symbols in the symbol dictionary in the order symbols are extracted from the binary images.

### CROSS-REFERENCE TO RELATED APPLICATIONS

This application claims benefit under 35 U.S.C. § 119(a) of Korean Patent Application Serial No. 2004-95859, filed on Nov. 22, 2004, the entire contents of which are hereby incorporated by reference.

### BACKGROUND OF THE INVENTION

1. Field of the Invention

The present invention relates to a binary image-processing device and method. More particularly, the present invention relates to a binary image-processing device and method using symbol dictionary rearrangement in order to minimize the occurrence of differences over original images and substitution errors.

2. Description of the Related Art

There are many coding methods including the Modified Huffman (MH) coding method, Modified READ (MR) coding method, Modified Modified READ (MMR) coding method, Joint Bi-level Image Experts Group (JBIG), and so on, as lossless compression methods applied to binary images. Of these methods, the MR and MMR are the encoding algorithms applied to G3 and G4 fax standards, and so on, and the JBIG is a context-based arithmetic coding algorithm. Recently, the Joint Bi-level Image Experts Group-2 (JBIG2) has been implemented as a standard defined by ITU-T Recommendation T.88.

In general, documents created in binary images are mixed with images identified as symbols such as text, signs, and so on, and images identified as non-symbols such as line-art and half-tone images.

The JBIG2 method compresses image data identified as symbols such as text or signs by using the coding method based on symbol matching, and compresses the other image components such as image data like line-art or half-tone images by using the arithmetic coding algorithm based on context or halftone-coding methods.

As above, data compressed by different image compression methods is sent in segment units, and, in particular, the image components compressed by the image-coding method based on the symbol matching are represented with symbol dictionary segments and symbol region segments. In the symbol dictionary segments, symbol bitmaps repeatedly used in binary images are compressed by the MMR or the arithmetic coding algorithm, and the width and height of each of the symbols are compressed by the Huffman coding method or the arithmetic coding method.

In the symbol region segments, the positions and symbol dictionary indexes of symbols contained in binary images are compressed and sent by the Huffman coding method or the arithmetic coding method.

The coding method based on symbol matching extracts symbols from inputted binary images, and determines whether symbols matching with the extracted symbols exist in the dictionary or the library. Typically, the images extracted as symbols refer to images like text.

As a result of the search, if it is decided that there exists a symbol matching with the symbol dictionary or the symbol extracted from the library, the symbol index information stored in the dictionary is used for the symbol to be coded. To the contrary, if the symbol matching with the symbol extracted from the dictionary does not exist, the extracted symbol is added to the existing symbol dictionary, and the index information of the added symbol is used for the symbol to be coded.

However, if the symbol dictionary is built based on the above method, there exists a drawback in that representative symbols are determined according to the symbol-extracting order when registered in the symbol dictionary. If symbols registered in a symbol dictionary are able to represent many similar symbols out of the entire symbols of a binary image, the compression efficiency becomes high and the substitution error becomes low. Substitution errors refer to errors occurring when a specific symbol is substituted with a similar symbol having a different definition. FIGS. 1A to 1C are views for showing a conventional symbol-extracting order and symbol registration result. In FIGS. 1A to 1C, the superscript numbers denote symbol-occurring order. FIG. 1A shows a symbol matching result at the time the first symbol F¹ and the second symbol F² are extracted. In FIG. 1A, the circles denote virtual spaces representative of cluster regions. A cluster refers to a virtual circular region including all representative symbols registered in the symbol dictionary and at least one or more symbols similar to the representative symbols. FIG. 1B shows a symbol registration result at the time the fifth symbol is extracted. In FIG. 1B, it is decided that symbols F³, E⁴, F⁵, and so on, belonging to the cluster region to which the representative symbol F² (or the center symbol) pertains are similar to the representative symbol F². FIG. 1C shows a symbol registration result at the time the ninth symbol is extracted. In FIG. 1B, the fourth symbol E⁴ matches with the first symbol F¹, but it can be seen in FIG. 1C that the fourth symbol E⁴ is more similar to the ninth symbol E⁹ later extracted. In the case of particular symbols such as the fourth symbol E⁴ existing on the boundary of similar symbols, there exists a problem of lower compression efficiency and a higher occurrence of substitution errors.

### SUMMARY OF THE INVENTION

The present invention has been developed in order to solve the above drawbacks and other problems associated with the conventional arrangement, and to provide advantages which will be apparent from the following description. An aspect of the present invention is to provide a binary image-processing device and method using symbol dictionary rearrangement in order to improve compression efficiency and to minimize substitution errors by building a symbol dictionary a first time and rearranging the symbol dictionary for entire symbols to be re-assigned to a cluster to which their nearest registration symbols pertain.

The foregoing and other objects and advantages are substantially realized by providing a binary image-processing device, comprising a symbol-extracting unit for extracting symbols from an inputted binary image; a symbol-matching unit for matching an extracted symbol with a previously registered symbol and building a symbol dictionary; and a symbol dictionary rearrangement unit for re-arranging the symbol dictionary.

Preferably, the symbol-matching unit calculates a minimum value out of distances between a certain symbol extracted by the symbol-extracting unit and registered symbols of the symbol dictionary, compares the calculated minimum value to a predetermined threshold value, and, if the calculated minimum value is larger than the threshold value, registers the extracted symbol in the symbol dictionary and stores an index of the registered symbol.

Preferably, the binary image-processing device further comprises a first compression-unit for compressing registered symbols in the symbol dictionary re-arranged based on the re-set index by the symbol dictionary rearrangement unit, and producing a compressed symbol; a second compression unit for compressing a symbol area of a binary image to produce a compressed symbol area based on indices of registered symbols re-arranged in the symbol dictionary and information of positions of symbols extracted from the symbol-extracting unit, and an output unit for producing for an output a compressed bit stream based on the compressed symbol and the compressed symbol area respectively provided from the first and second compression units.

Preferably, the symbol dictionary rearrangement unit includes a cluster selecting unit for selecting plural clusters out of the symbol dictionary; a symbol selecting unit for selecting a certain symbol belonging to a previously produced cluster of the plural clusters; a comparison unit for comparing a first distance D1 between the symbol selected by the symbol selecting unit and a registered symbol of a cluster to which the selected symbol belongs and a second distance D2 between the selected symbol and a registered symbol of a different cluster to which the selected symbol does not belong, if a distance between the clusters is smaller than a second threshold value; and a rearrangement unit for re-arranging a cluster to which the symbol belongs and newly designating an index of the selected symbol, if the second distance D2 is smaller than the first distance D1.

Another aspect of the present invention is to provide a binary image-processing method, comprising the steps of extracting symbols from an inputted binary image; matching an extracted symbol with a previously registered symbol and building a symbol dictionary; and re-arranging the symbol dictionary.

Preferably, the symbol-matching step includes steps of calculating a minimum value out of distances between a certain extracted symbol and previously registered symbols of the symbol dictionary, and comparing the calculated minimum value to a predetermined threshold value; and registering the extracted symbol in the symbol dictionary and storing an index of the registered symbol, if the calculated minimum value is larger than the threshold value.

Further, preferably, if the calculated minimum value is smaller than the threshold value as a result of the comparison, it is determined that there exists in the symbol dictionary a similar registered symbol matching with the extracted symbol, and an index of the registered symbol is stored.

Preferably, the binary image-processing method further comprises a first compression step of compressing registered symbols in the symbol dictionary re-arranged based on the re-set indices by the symbol dictionary rearrangement, and producing a compressed symbol; and a second compression step of compressing a symbol area of a binary image to produce a compressed symbol area based on indices of registered symbols re-arranged in the symbol dictionary and information of positions of symbols extracted from the symbol-extracting step; and an output step of producing for an output a compressed bit stream based on the compressed symbol and the compressed symbol area respectively produced from the first and second compression steps.

Preferably, the symbol dictionary rearrangement step includes (a) a cluster selecting step for selecting plural clusters out of the symbol dictionary; (b) a symbol selecting step for selecting a certain symbol belonging to a previously produced cluster of the plural clusters, if a distance between the clusters is smaller than a second threshold value; (c) a comparison step for comparing a first distance D1 between the selected symbol and a registered symbol of a cluster to which the selected symbol belongs and a second distance D2 between the selected symbol and a registered symbol of a different cluster to which the selected symbol does not belong; and (d) a rearrangement step for re-arranging a cluster to which the symbol belongs and newly designating an index of the selected symbol, if the second distance D2 is smaller than the first distance D1.

Preferably, the binary image-processing method further comprises a: step of calculating the first distance D1 between the symbol selected in the step (b) and the registered symbol of the cluster to which the selected symbol belongs and a third distance between the registered symbol of the cluster to which the selected symbol belongs and a registered symbol of a cluster to which the selected symbol does not belong, and comparing the first distance D1 to half the third distance D3, wherein, if the first distance D1 is smaller than half the third distance D3 as a result of the comparison, the symbol dictionary rearrangement is not performed over the selected symbol, and, if the first distance D1 is larger than half the third distance D3, steps (c) and (d) are performed.

### BRIEF DESCRIPTION OF THE DRAWINGS

The above aspects and features of the present invention will be more apparent by describing certain embodiments of the present invention with reference to the accompanying drawings, in which:

FIGS. 1A to 1C are views for showing conventional symbol extraction order and a symbol registration result;

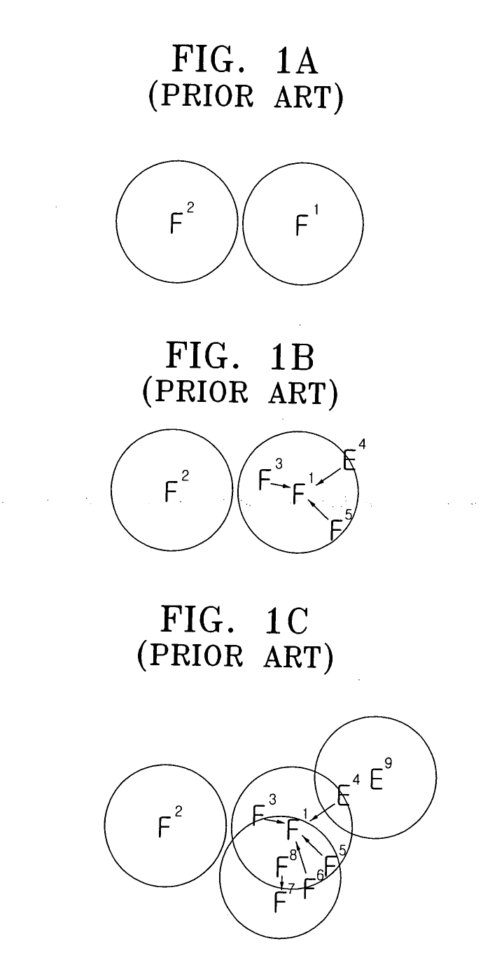

FIG. 2 is a block diagram showing a structure of a binary image-processing device using a symbol dictionary rearrangement according to an embodiment of the present invention;

FIG. 3 is a block diagram showing a structure of the symbol dictionary rearrangement unit shown in FIG. 2;

FIG. 4 is a flow chart illustrating a binary image-processing method using a symbol dictionary rearrangement according to an embodiment of the present invention;

FIG. 5 is a flow chart for explaining in detail one embodiment of step S430 shown in FIG. 4; and

FIG. 6 is a flow chart for explaining in detail another embodiment of the step S430 shown in FIG. 4.

Throughout the drawings, life reference numbers will be understood to refer to like features, structures and elements.

### DETAILED DESCRIPTION OF EXEMPLARY EMBODIMENTS

Hereinafter, exemplary embodiments of the present invention will be described in detail with reference to the attached drawings.

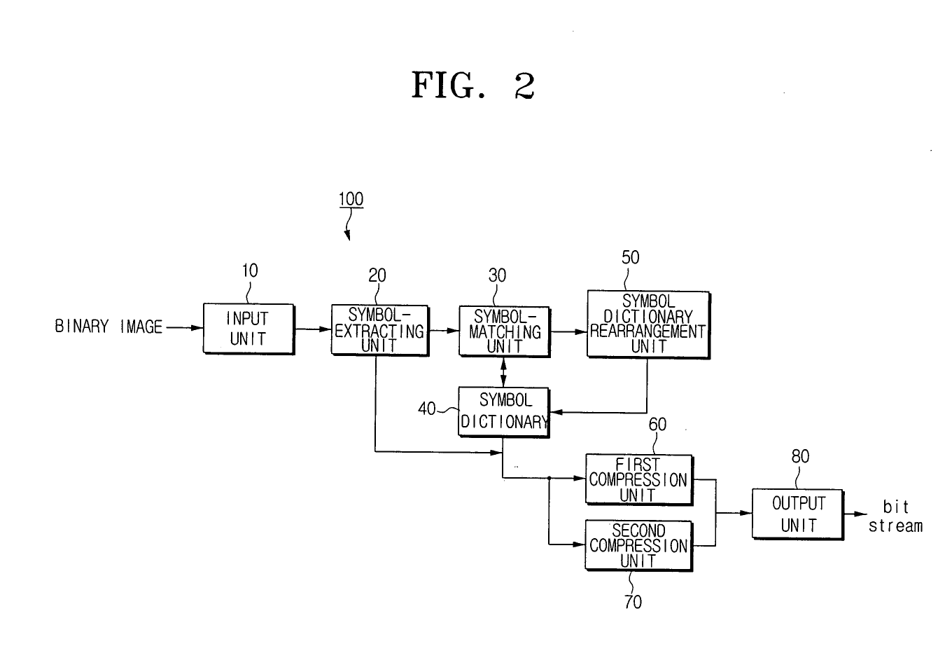

FIG. 2 is a block diagram showing a structure of a binary image-processing device using a symbol dictionary rearrangement according to an embodiment of the present invention. In FIG. 2, the binary image-processing device 100 comprises an input unit 10, a symbol-extracting unit 20, a symbol-matching unit 30, a symbol dictionary 40, a symbol dictionary rearrangement unit 50, a first compression unit 60, a second compression unit 70, and an output unit 80.

The input unit 10 receives a binary image and sends the binary image to the symbol-extracting unit 20. The symbol-extracting unit 20 identifies symbol regions from the inputted binary image, and extracts the symbols.

The symbol-matching unit 30 builds the symbol dictionary 40 by using the extracted symbol. That is, the symbol-matching unit 30 calculates a distance between the symbol extracted by the symbol-extracting unit 20 and at least one or more symbols registered in the symbol dictionary 40, compares a minimum value ‘min’ out of the calculated distances to a predetermined first threshold value Th1, performs symbol matchings, and builds a symbol dictionary. If a certain symbol is extracted for the first time, the symbol does not yet exist as a registered symbol in the dictionary. Thus, the symbol extracted for the first time is added as a representative symbol to the symbol dictionary.

If the minimum value ‘min’ is larger than the first threshold value Th1, a symbol similar to the extracted symbol does not yet exist in the symbol dictionary 40. Thus, the symbol-matching unit 30 newly registers the current extracted symbol in the symbol dictionary 40, and stores an index of the registered symbol. The indices preferably denote the numbers of the symbols registered in the symbol dictionary, and the numbers are preferably, but not necessarily, determined by the sizes of the symbols, that is, the heights and widths.

On the other hand, if the minimum value ‘min’ is smaller than the first threshold value Th1, it is determined that a symbol similar to the current extracted symbol exists in the symbol dictionary 40. Thus, the symbol-matching unit 30 stores only the index of the symbol similar to the extracted symbol without adding the current extracted symbol to the symbol dictionary 40.

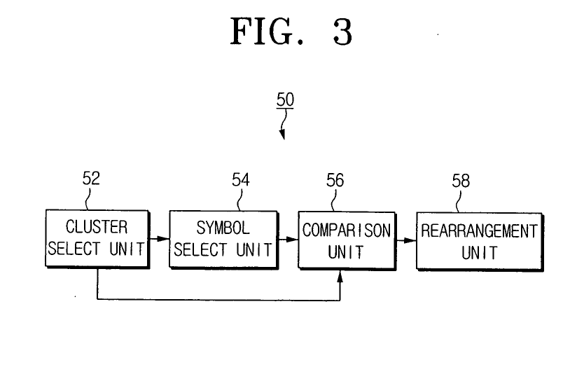

The symbol dictionary rearrangement unit 50 re-arranges the symbol dictionary 40 if all the symbols are extracted from a binary image and the symbol dictionary 40 is completely built. FIG. 3 is a block diagram for showing an exemplary structure of the symbol dictionary rearrangement unit shown in FIG. 2.

The symbol dictionary rearrangement unit 50 has a cluster selecting unit 52, a symbol selecting unit 54, a comparison unit 56, and a rearrangement-unit 58. The cluster selecting unit 52 selects two clusters nearest in distance from the symbol dictionary 40. In the present disclosure, a cluster refers to a virtual circular area including both registration symbols registered in the symbol dictionary and at least one or more symbols similar to the registration symbols. The registration symbol is located in the center of a cluster.

The symbol selecting unit 54 selects a certain symbol out of at least one or more symbols included in a previously created cluster.

The comparison unit 56 compares a distance between two clusters to a predetermined second threshold value Th2, and, if the distance between the clusters is larger than the second threshold value Th2, ends a symbol dictionary rearrangement process, since it is not necessary to continue rearranging the symbol dictionary. On the other hand, if the distance between the clusters is smaller than the second threshold value Th2, the comparison unit 56 compares a distance between a certain symbol selected by the symbol selecting unit 54 and a representative symbol of a cluster to which the selected symbol belongs to a distance between the selected symbol and a representative symbol of a different cluster to which the selected symbol does not belong.

The rearrangement unit 58 re-designates a cluster to which the symbols selected according to a comparison result of the comparison unit 56 belong, and re-arranges the indices of the symbols.

If the symbol dictionary is re-arranged by the symbol dictionary rearrangement unit 50, the first and second compression units 60 and 70 perform image compression. The first compression unit 60 compresses the symbols registered in the symbol dictionary 40 based on the re-arranged indices.

The second compression unit 70 compresses a symbol area of the binary image based on the indices of the symbols registered in the symbol dictionary 40 and the information of positions of the symbols extracted by the symbol-extracting unit 20.

The output unit 80 inputs the compressed symbols and the compressed symbol region from the first compression unit 60 and the second compression unit 70, respectively, and produces a final binary image compression bit stream for output.

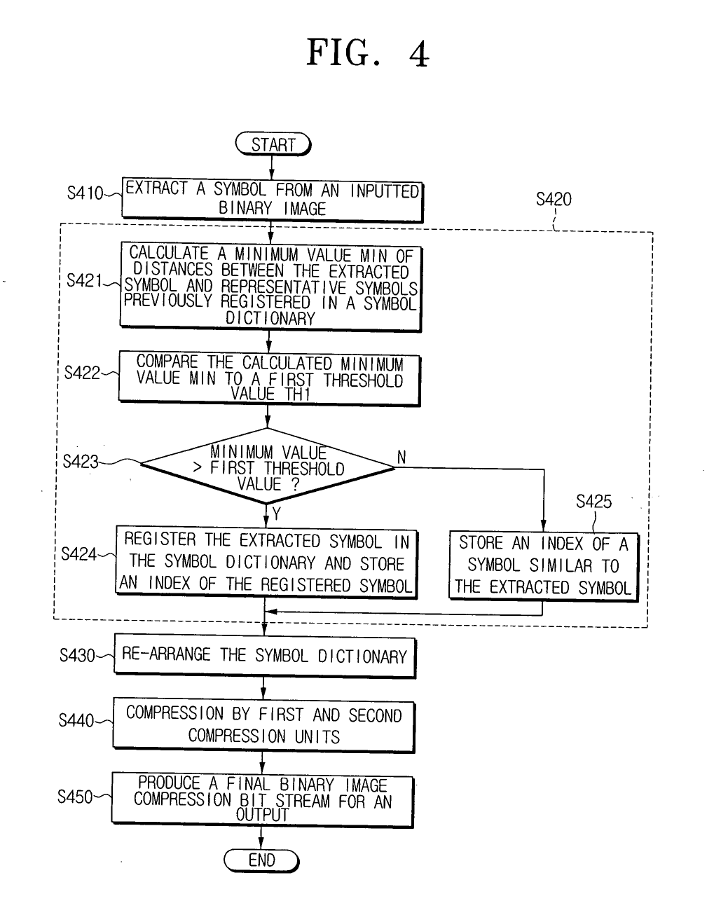

FIG. 4 is a flow chart for explaining a binary image-processing method using symbol dictionary rearrangement according to an embodiment of the present invention. In FIGS. 2 and 4, the symbol-extracting unit 20 first extracts symbols from a binary image provided from the input unit 10 (S410).

That is, the symbol-extracting unit 20 identifies a symbol region from the binary image, determines whether the image in the identified area is a symbol image or a non-symbol image, and extracts data of the image determined as symbols.

In here, the symbol image indicates an image identified as text such as characters (A, B), signs, numbers, and so on, and the non-symbol image indicates an image such as halftone images. The method for determining whether an image of each divided region is symbol images or non-symbol images is disclosed in Korean Patent Application No. P2004-0027983 filed by the same Applicant, so a detailed description thereof will be omitted here for conciseness and clarity.

The symbol-matching unit 30 uses the extracted symbols to build the symbol dictionary 40 (S420). Description will now be made in more detail of a process for building the symbol dictionary.

First, the symbol-matching unit 30 calculates a minimum value ‘min’ out of distances between a certain symbol extracted by the symbol-extracting unit 20 and at least one or more registration symbols registered in the symbol dictionary 40 (S421). Next, the symbol-matching unit 30 compares the calculated minimum value ‘min’ and the first threshold value Th1 (S422).

If the calculated minimum value ‘min’ is larger than the first threshold value Th1 as a comparison result of step S422, then it is determined that a symbol similar to the extracted symbol does not exist in the symbol dictionary (S423). Thus, in such a case, the symbol-matching unit 30 registers the current extracted symbol in the symbol dictionary 40, and stores an index of the registered symbol (S424). The symbol registered in the symbol dictionary is preferably stored as a bitmap image.

On the other hand, if the calculated minimum value ‘min’ is smaller than the first threshold value Th1 (S423), then it is determined that a symbol similar to the extracted symbol does exist in the symbol dictionary. Thus, the symbol-matching unit 30 does not add the current extracted symbol to the symbol dictionary 40, but stores an index of the symbol similar to the extracted symbol (S425).

If the symbol dictionary is completely built according to the above process, the symbol dictionary is re-arranged (S430). Description will be later made in detail on a symbol dictionary rearrangement process.

If the symbol dictionary is completely rearranged in the step S430, the first and second compression units 60 and 70 performs compressions (S440).

The first compression unit 60 compresses the registered symbols of the symbol dictionary 40 based on the re-arranged indices. The registered symbols of the symbol dictionary 40 are compressed according to the MMR method or the context-based: compression method similar to the JBIG or the like, and the sizes and size differences of the symbols are compressed according to the Huffman coding method, the arithmetic coding method, or the like. Since the registered symbols are stored as bitmap images, the compression of the symbol sizes and size differences refers to the compression of the widths and heights of the bitmap images. In here, the width and height are not compressed as they are, but symbols having the same height are arranged in order of increasing their widths, the width of a symbol appearing for the first time is compressed as it is, and the width of the next symbol is compressed by a difference over the width of the first symbol appearing just before. The above compression method enables the symbols to be compressed into fewer bits. The second compression unit 70 uses the indices of the registered symbols of the symbol dictionary 40 and the position information on the extracted symbols from the symbol-extracting unit 20 to compress a symbol region of a binary image. The Huffman, arithmetic coding method, and so on, can be applied by the second compression unit 70.

The compressed symbol region and symbol of the first and second compression units 60 and 70 are sent to the output unit 80, and the output unit 80 inputs the compressed symbol and the compressed symbol region from the first compression unit 60 and the second compression unit 70, respectively, and produces a final binary image compression bit stream for output (S450).

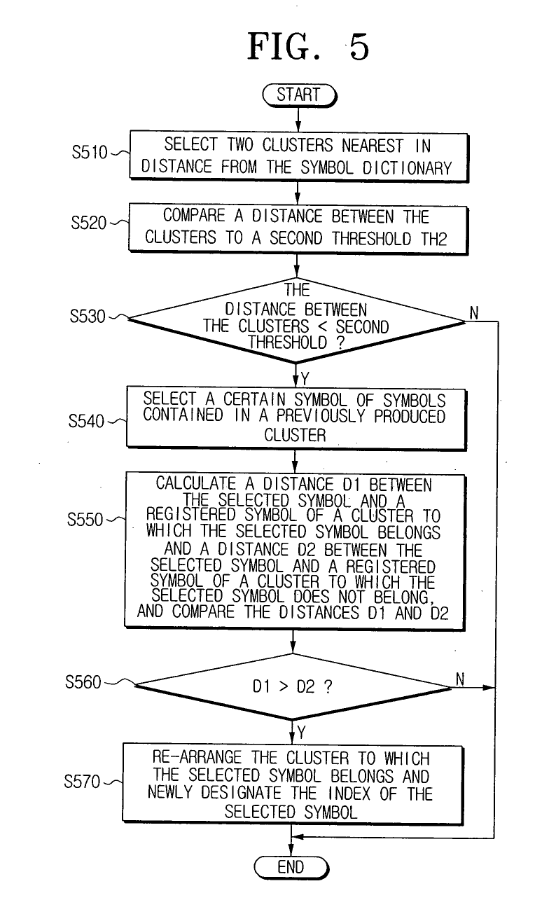

FIG. 5 is a flow chart explaining in detail an embodiment of step S430 of FIG. 4. In FIG. 5, the cluster selecting unit 52 selects two clusters nearest in distance from the symbol dictionary 40 (S510). Next, the comparison unit 56 compares the distance between the two clusters and the second threshold value Th2 (S520).

If the distance between the clusters is smaller than the second threshold value Th2 as a result of the comparison (S530), the symbol select unit 54 selects a certain symbol out of at least one or more symbols contained in a previously produced cluster (S540).

On the contrary, if the distance between the clusters is larger than the second threshold value Th2 (S530), the symbol dictionary rearrangement process is completely ended, since it is not necessary to keep rearranging the symbol dictionary any further.

Next, the comparison unit 56 calculates a first distance D1 between a certain symbol selected by the symbol select unit 54 and a registered symbol of a cluster to which the selected symbol belongs and a second distance D2 between the selected symbol and a registered symbol of a cluster to which the selected symbol does not belong, and compares the both distances (S550).

If the second distance D2 is smaller than the first distance D1 as a result of the comparison (S560), then it is determined that the selected symbol is more similar to the registered symbol of a different cluster to which the selected symbol does not belong. Thus, the rearrangement unit 58 re-arranges a cluster to which the selected symbol belongs, and newly designates an index of the selected symbol (S570). However, if the first distance D1 is smaller than the second distance D2 (S560), the rearrangement unit 58 does not re-arrange the selected symbol.

If the above process is completely ended, the steps S540 to S570 are performed over the other symbols of the cluster to which the selected symbol belongs. Further, if the above process is executed, two clusters being next nearest in the symbol dictionary are selected, and the step S520 to S570 are repeated over the two clusters.

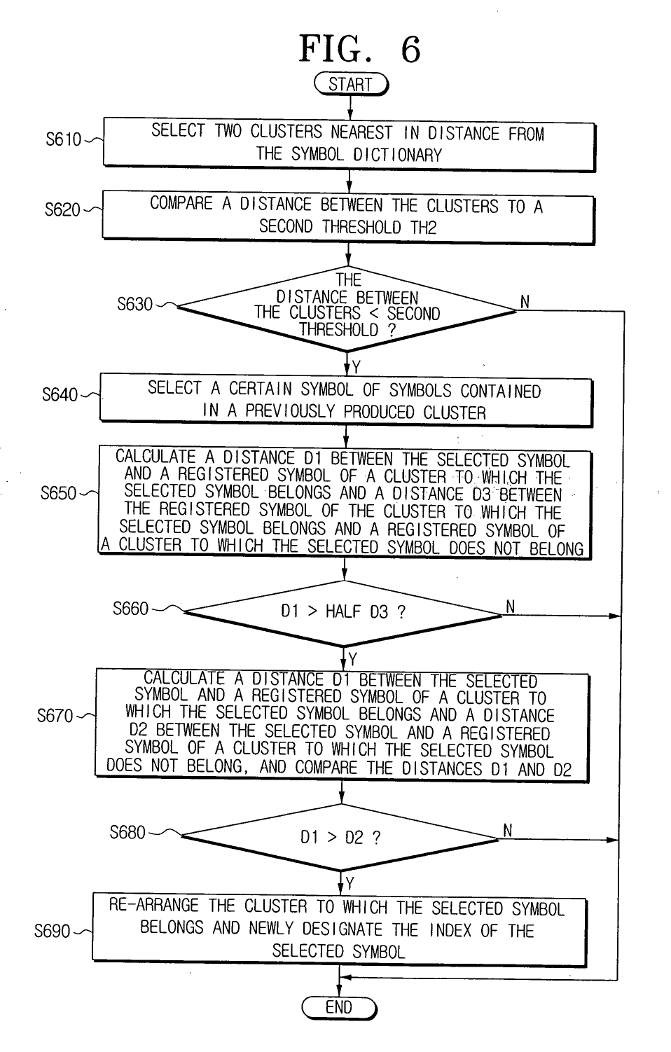

FIG. 6 is a flow chart explaining in detail another embodiment of the step S430 of FIG. 4. Steps S610-S640 are substantially similar to steps S510-S540 of FIG. 5, and therefore their description will not be repeated here. In FIG. 6, between the steps S540 and S550, the comparison unit 56 further calculates a first distance D1 between a selected symbol and a registered symbol of a cluster to which the selected symbol belongs and a third distance D3 between the registered symbol of a cluster to which the selected symbol belongs and a registered symbol of a cluster to which the selected symbol does not belong (S650), and compares the first distance D1 to a half of the third distance D3 (S660).

If the first distance D1 is smaller than half the third distance D3 as a result of the comparison of the step S660, the rearrangement unit 58 does not re-arrange the symbol dictionary over the selected symbol, and, if the first distance D1 is larger than half the third distance D3, the rearrangement unit 58 runs the step S670. The operations after the step S670 are the same after the step S550 of FIG. 5, so a detailed description will be omitted.

The above process re-arranges the symbol dictionary, so as to minimize substitution errors being hardly avoided in the compression of binary images.

As aforementioned, embodiments of the present invention re-arrange symbols extracted from binary images, thereby bringing an advantage of eliminating the conventional inefficiency caused by registering the symbols in the symbol dictionary in the same order in which the symbols are extracted from binary images.

Further, embodiments of the present invention select registered symbols similar to symbols extracted from binary images based on symbol dictionary rearrangement, and then perform image compressions, so as to bring an advantage of minimizing bit differences over an original image.

Further, embodiments of the present invention have an advantage of minimizing substitution errors that are difficult to avoid upon compression of binary images.

The foregoing embodiments and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. A binary image-processing device, comprising:
a symbol-extracting unit for extracting symbols from an inputted binary image;
a symbol-matching unit for matching an extracted symbol with a previously registered symbol and building a symbol dictionary; and
a symbol dictionary rearrangement unit for re-arranging the symbol dictionary.

2. The binary image-processing device as claimed in claim 1, wherein the symbol-matching unit calculates a minimum value out of distances between a certain symbol extracted by the symbol-extracting unit and registered symbols of the symbol dictionary, compares the calculated minimum value to a predetermined threshold value, and, if the calculated minimum value is larger than the threshold value, registers the extracted symbol in the symbol dictionary and stores an index of the registered symbol.

3. The binary image-processing device as claimed in claim 2, wherein the index indicates the number of the registered symbol of the symbol dictionary, and the number is determined based on a size of the symbol.

4. The binary image-processing device as claimed in claim 2, wherein, if the calculated minimum value is larger than the threshold value, it is determined that a similar symbol for matching the extracted symbol does not exist in the dictionary.

5. The binary image-processing device as claimed in claim 2, wherein, if the calculated minimum value is smaller than the threshold value, it is determined that there exists in the symbol dictionary a similar registered symbol matching with the extracted symbol, and an index of the registered symbol is stored.

6. The binary image-processing device as claimed in claim 1, wherein the symbol is an image identified as text such as characters, signs, numbers, or the like.

7. The binary image-processing device as claimed in claim 1, further comprising:
a first compression unit for compressing registered symbols in the symbol dictionary re-arranged based on the re-set index by the symbol dictionary rearrangement unit, and producing a compressed symbol; and
a second compression unit for compressing a symbol area of binary image to produce a compressed symbol area based on indices of registered symbols re-arranged in the symbol dictionary and information of positions of symbols extracted from the symbol-extracting unit.

8. The binary image-processing device as claimed in claim 7, further comprising an output unit for producing a compressed bit stream for output based on the compressed symbol and the compressed symbol area respectively provided from the first and second compression units.

9. The binary image-processing device as claimed in claim 1, wherein the symbol dictionary rearrangement unit includes:
a cluster selecting unit for selecting plural clusters out of the symbol dictionary;
a symbol selecting unit for selecting a certain symbol belonging to a previously produced cluster of the plural clusters;
a comparison unit for comparing a first distance D1 between the symbol selected by the symbol select unit and a registered symbol of a cluster to which the selected symbol belongs and a second distance D2 between the selected symbol and a registered symbol of a different cluster to which the selected symbol does not belong, if a distance between the clusters is smaller than a second threshold value; and
a rearrangement unit for re-arranging a cluster to which the symbol belongs and newly designating an index of the selected symbol, if the second distance D2 is smaller than the first distance D1.

10. The binary image-processing device as claimed in claim 9, wherein the cluster is a virtual circular area including both the registered symbol of the symbol dictionary and at least one or more symbols similar to the registered symbol, and the registered symbol is located in the center of the cluster.

11. The binary image-processing device as claimed in claim 9, wherein the cluster selecting unit selects the plural clusters in ascending order of the distances between the clusters.

12. A binary image-processing method, comprising steps of:
extracting symbols from an inputted binary image;
matching an extracted symbol with a previously registered symbol and building a symbol dictionary; and
re-arranging the symbol dictionary.

13. The binary image-processing method as claimed in claim 12, wherein the symbol-matching step includes steps of:
calculating a minimum value out of distances between a certain extracted symbol and previously registered symbols of the symbol dictionary, and comparing the calculated minimum value to a predetermined threshold value; and
registering the extracted symbol in the symbol dictionary and storing an index of the registered symbol, if the calculated minimum value is larger than the threshold value.

14. The binary image-processing method as claimed in claim 13, wherein the index indicates the number of the registered symbol of the symbol dictionary, and the number is determined based on a size of the symbol.

15. The binary image-processing method as claimed in claim 13, wherein, if the calculated minimum value is smaller than the threshold value as a result of the comparison, it is determined that there exists in the symbol dictionary a similar registered symbol matching the extracted symbol, and an index of the registered symbol is stored.

16. The binary image-processing method as claimed in claim 12, further comprising:
a first compression step for compressing registered symbols in the symbol dictionary re-arranged based on the re-set indices by the symbol dictionary rearrangement, and producing a compressed symbol; and
a second compression step for compressing a symbol area of binary image to produce a compressed symbol area based on indices of registered symbols re-arranged in the symbol dictionary and information of positions of symbols extracted from the symbol-extracting step.

17. The binary image-processing method as claimed in claim 16, further comprising an output step for producing a compressed bit stream for output based on the compressed symbol and the compressed symbol area respectively produced from the first and second compression steps.

18. The binary image-processing method as claimed in claim 12, wherein the symbol dictionary rearrangement step includes:
(a) a cluster selecting step for selecting plural clusters out of the symbol dictionary;
(b) a symbol selecting step for selecting a certain symbol belonging to a previously produced cluster of the plural clusters, if a distance between the clusters is smaller than a second threshold value;
(c) a comparison step for comparing a first distance D1 between the selected symbol and a registered symbol of a cluster to which the selected symbol belongs and a second distance D2 between the selected symbol and a registered symbol of a different cluster to which the selected symbol does not belong; and
(d) a rearrangement step for re-arranging a cluster to which the selected symbol belongs and newly designating an index of the selected symbol, if the second distance D2 is smaller than the first distance D1.

19. The binary image-processing method as claimed in claim 18, further comprising a step of
calculating the first distance D1 between the symbol selected in the step (b) and the registered symbol of the cluster to which the selected symbol belongs and a third distance D3 between the registered symbol of the cluster to which the selected symbol belongs and a registered symbol of a cluster to which the selected symbol does not belong, and comparing the first distance D1 to half the third distance D3, wherein, if the first distance D1 is smaller than half the third distance D3 as a result of the comparison, the symbol dictionary rearrangement is not performed over the selected symbol, and, if the first distance D1 is larger than half the third distance D3, the steps (c) and (d) are performed.

20. The binary image-processing method as claimed in claim 18, wherein the cluster is a virtual circular area including both the registered symbol of the symbol dictionary and at least one or more symbols similar to the registered symbol, and the registered symbol is located in the center of the cluster.

21. The binary image-processing method as claimed in claim 18, wherein the plural clusters are selected in ascending order of the distances between the clusters.
